(19) United States
(12) Patent Application Publication
(10) Pub. No.: US 2010/0206370 A1
(43) Pub. Date: Aug. 19, 2010

(54) Photovoltaic Cell Efficiency Using Through Silicon Vias

(75) Inventors: Thomas R. Toms, Dripping Springs, TX (US); Shiqun Gu, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/372,778

(22) Filed: Feb. 18, 2009

(51) Int. Cl. H01L 31/00

(52) U.S. Cl. 136/256

(57) ABSTRACT

A photovoltaic cell includes a photovoltaic layer having a first node and a second node. A first conductive layer is electrically coupled to the second node of the photovoltaic layer so the first conductive layer does not block light from the photovoltaic layer. A second conductive layer is adjacent to but electrically insulated from the first conductive layer, so the second conductive layer is positioned where it does not block light from the photovoltaic layer. At least one through silicon via is electrically coupled to the first node of the photovoltaic layer and the second conductive layer, but is electrically insulated from at least a portion of the photovoltaic layer and the first conductive layer.

### TECHNICAL FIELD

The present disclosure relates generally to photovoltaic cells. More specifically, the present disclosure relates to reducing light obstruction by using through silicon vias.

### BACKGROUND

Conventional solar cells receive energy from a light source such as the sun, and convert the energy into electricity. Conventional solar cells generally include a photovoltaic layer that receives light photons and converts those photons into electricity. To enhance efficiency, a conductive electrode layer such as one made of Indium-Tin-Oxide, with an irregular surface has been used to deflect more photons into the photovoltaic layer. In such an arrangement, metallic traces are positioned on top of the electrode layer on one side and a metallic layer is positioned on the other side of the photovoltaic layer. A load connected between the metallic traces on the one side and the metallic layer on the other side of the photovoltaic layer provides a conduction path for the generated electricity. In such an arrangement, the metallic traces, being on the light receiving side of the photovoltaic cell, will obstruct some light from entering into the photovoltaic layer and hence will reduce the efficiency of the solar cell.

One way to increase efficiency has been to reduce the size of the metallic traces so that more photons enter the photovoltaic layer. However, reducing the trace size also increases internal resistance of the solar cell, thus reducing efficiency. Another solution has been to reduce the thickness of the electrode layer without decreasing the size of the metallic traces to reduce the amount of light absorbed by the electrode layer. However, the reduced thickness of the electrode layer causes increased internal resistance and the light continues to be obstructed by the metallic traces.

Thus, what is needed is a photovoltaic cell structure that will reduce the obstruction of light to the photovoltaic cell from the metallic traces and thereby increase the efficiency of the photovoltaic cell without increasing the internal resistance of the photovoltaic cell.

### BRIEF SUMMARY

In one embodiment, a photovoltaic cell includes a photovoltaic layer with a first node and a second node. A first conductive layer is electrically coupled to the second node of the photovoltaic layer. A second conductive layer is positioned adjacent to but electrically insulated from the first conductive layer on the second node of the photovoltaic layer, so that the second conductive layer will not block light impinging on the first node of the photovoltaic layer. At least one through silicon via is electrically coupled from the first node of the photovoltaic layer to the second conductive layer, with the through silicon via passing through but electrically insulated from the body of the photovoltaic layer and the first conductive layer.

In another embodiment, a light refracting layer can be coupled to the first node of the photovoltaic layer to deflect light into the photovoltaic layer. However, because the through silicon via is electrically coupled directly to the first node, the light refracting layer does not need to be an electrode layer and does not need to be conductive and therefore can have a structure that reduces light absorption without increasing the internal resistance.

In still another embodiment, an apparatus for reducing obstruction of light to a photovoltaic cell includes a means for receiving light and absorbing the light to generate electricity between polarized nodes. A first means for conducting electricity from a first polarized node of the light receiving means while not blocking light from the light receiving means is also included. Finally, a second means for conducting electricity from a second polarized node of the light receiving means while not blocking light from the light receiving means is included in the apparatus.

In yet another embodiment, a method of reducing blocked light to a solar cell includes positioning a photovoltaic layer having a first node and a second node. A first conductive layer is then positioned adjacent to and electrically coupled to the second node of the photovoltaic layer so the first conductive layer does not block light from the photovoltaic layer. A second conductive layer is then positioned adjacent to and electrically insulated from the first conductive layer, so the second conductive layer does not block light from the photovoltaic layer. Finally, at least one through silicon via is then fabricated between the first node of the photovoltaic layer through the photovoltaic layer and the first conductive layer to the second conductive layer while at least one through silicon via is electrically insulated from the photovoltaic layer and the first conductive layer.

The foregoing has broadly outlined the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a cross section of a conventional solar cell.

FIG. 2 is a top view of the conventional solar cell as depicted in FIG. 1.

FIG. 3 is a cross section of an exemplary photovoltaic cell using through silicon vias.

FIG. 4 is a top view of the photovoltaic cell as depicted in FIG. 3.

### DETAILED DESCRIPTION

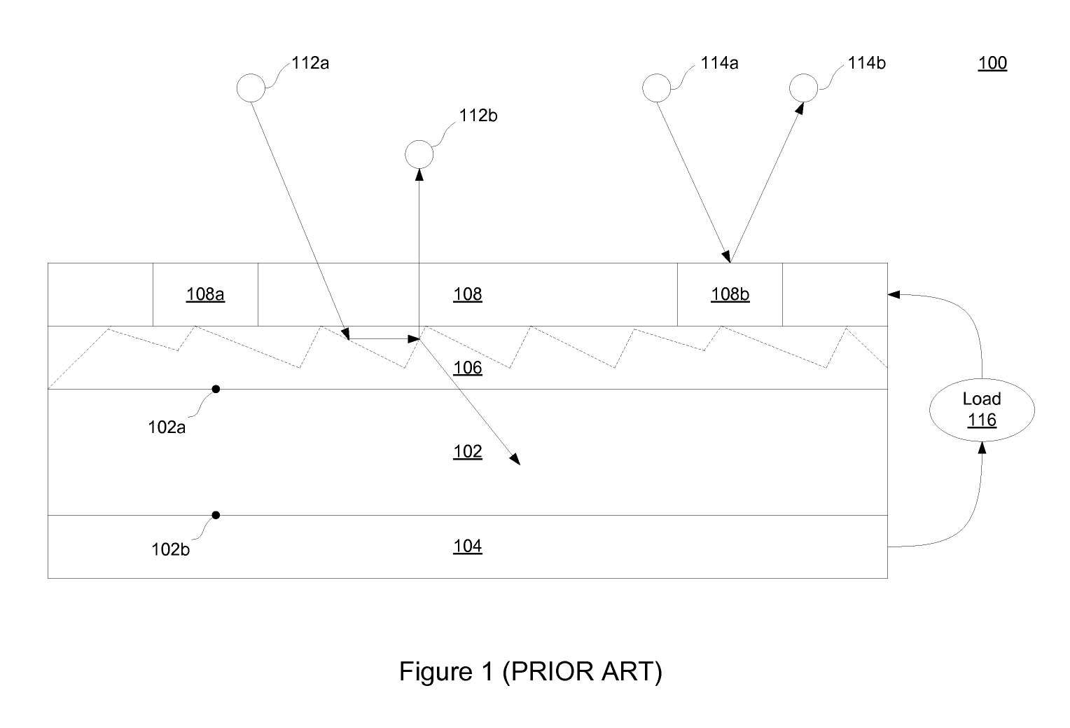

FIG. 1 is a cross section of a conventional solar cell 100 that includes a photovoltaic layer 102, a metal layer 104, an electrode layer 106, and a metal layer 108. The metal layer 104 is electrically coupled to a bottom node 102b of the photovoltaic layer 102 and electrically coupled to a load 116. The electrode layer 106 is conventionally composed of an Indium-Tin-Oxide material, which is approximately 90% In₂O₃ and 10% SnO₂. The electrode layer 106 is electrically coupled to a light receiving top node 102a of the photovoltaic layer 102. The electrode layer 106 is a conductive layer that deflects light into the photovoltaic layer 102 to increase electricity generation. The electrode layer 106 conventionally includes a scalloped surface, so photon 112a and photon 114b penetrate the electrode layer 106 at an angle to be reflected off the surface (e.g., photon 112b and photon 114b), or be deflected into the photovoltaic layer 102 and be absorbed. A metal layer 108 having metal traces (or electrical leads) such as metal traces 108a and 108b are positioned above and in electrically conductive relationship to the electrode layer 106.

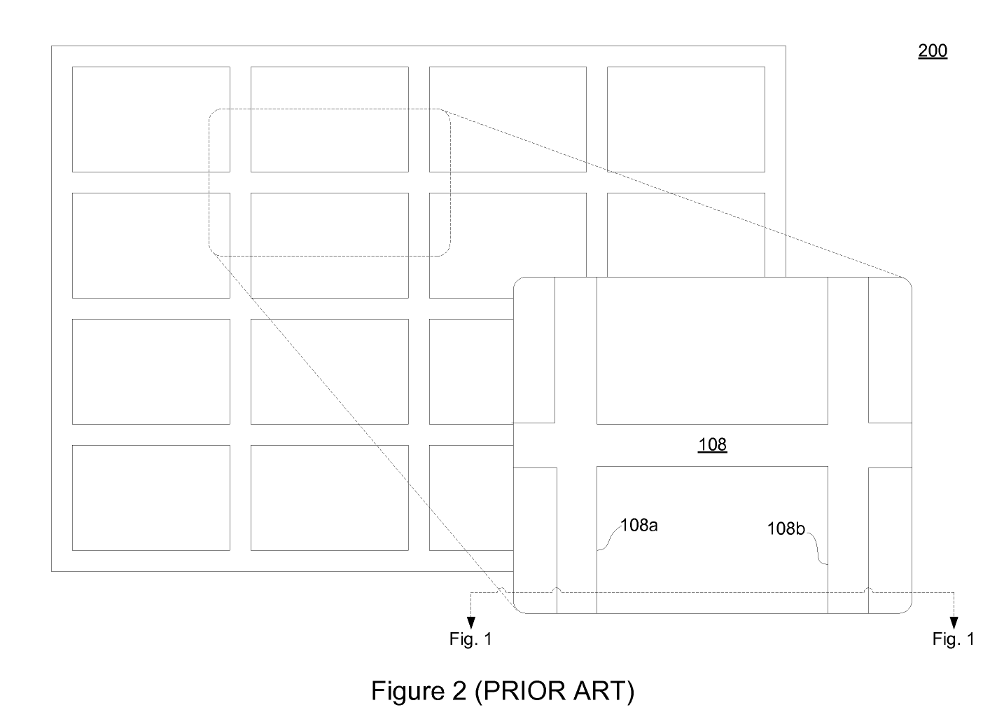

FIG. 2 is a top view of the solar cell 100 as depicted in FIG. 1 showing the metal layer 108 with its metal traces 108a, 108b, 108c, and 108d disposed on the electrode layer 106 (FIG. 1) in electrically conducting relationship with the light receiving top node 102a of the photovoltaic layer 102. The metal layer 108 has a y-axis dimension defined as Y metal, and an x-axis dimension defined as X metal. Also, the photovoltaic layer 102 has a y-axis dimension defined as Y cell, and an x-axis dimension defined as X cell. Conventional metal connections to the electrode layer 106 (FIG. 1) are configured as a metal mesh that covers area on the photovoltaic layer 102, and has the traces 108a, 108b, 202, 204 that prevent light from impinging on the photovoltaic layer 102. The photons blocked by the conventional metal mesh can be estimated using the formula (X metal*(Y cell+Ymetal)+X cell*Ymetal)/((Y cell+Y metal)*(X cell+X metal)). The result is an estimate of the ratio of the surface area of the solar cell 100 that is blocked by the metal layer 108. The more areas of the light receiving top node 102a of the photovoltaic layer 102 that are blocked by the metal traces 108a, 108b, 202, 204, the less electricity that is generated and the less efficient the photovoltaic layer 102 will be.

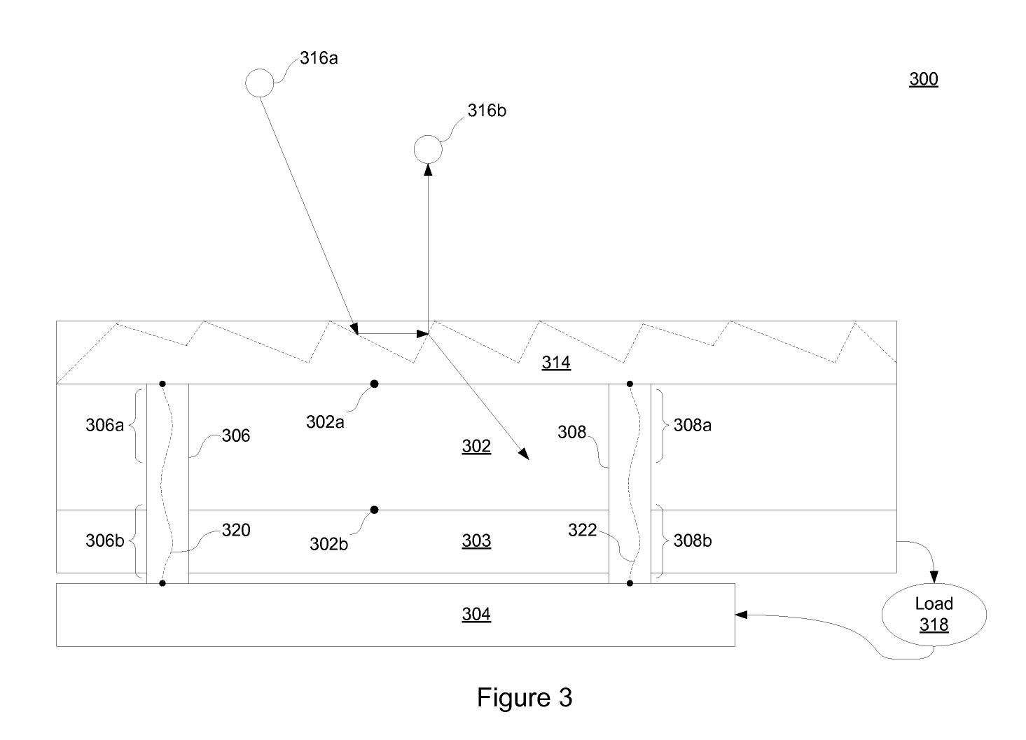

FIG. 3 is a cross section of an exemplary photovoltaic cell 300 with through silicon vias that extend through the photovoltaic layer 302 and so reduce the area of the side that would be blocked by the metal traces of conventional solar cells. When light photons impinge on the photovoltaic cell 300, complimentary charges are formed and flow through the photovoltaic layer 302 in opposite directions, resulting in polarized nodes (e.g., positive and negative poles). The photovoltaic cell 300 includes the photovoltaic layer 302 having polarized nodes such as a light receiving top node 302a, and a bottom node 302b opposite of the light receiving top node 302a. Although top and bottom nodes are described, of course other orientations are possible. In some embodiments, the photovoltaic layer 302 is made of a semiconductor material, such as one of Silicon (Si), Gallium Arsenide (GaAs), Cadmium Telluride (CdTe), and Copper Indium Diselenide (CuInSe₂). A first conductive layer 303 is electrically coupled to the bottom node 302b of the photovoltaic layer 302. A second conductive layer 304 is positioned where it will not block any light to the photovoltaic layer 302. For example, the second conductive layer 304 may be positioned adjacent to but electrically insulated from the first conductive layer 303. Because the second conductive layer 304 is adjacent to the first conductive layer 303, the surface area of the second conductive layer 304 can be continuous which reduces the internal resistance of the second conductive layer 304 so to improve efficiency. The first conductive layer 303 and the second conductive layer 304 can be made of a conductive material such as metal. Both the first conductive layer 303 and the second conductive layer 304 are electrically coupled to a load 318, so the load 318 can promote current flow between the first conductive layer 303 and the second conductive layer 304.

In some embodiments, at least one via, such as a through silicon via (TSV), is electrically coupled to the second conductive layer 304 and the light receiving top node 302a, so electricity generated by the photovoltaic layer 302 travels through the body of the photovoltaic layer 302 to the second conductive layer 304. The through silicon vias 306 and 308 can have a sloped profile (e.g., as a result of a wet etch process). The through silicon vias 306 and 308 can be any conductive material, such as a metal or a silicon material, that conducts electricity through the photovoltaic cell 300. Each of the through silicon vias 306 and 308 respectively have first ends 306a, 308a electrically coupled to the light receiving top node 302a. Because the footprint of the first ends 306a and 308a are substantially smaller than the metal layer 108 as shown in FIG. 1, less light is blocked from entering the photovoltaic layer 302 thereby increasing the electrical generating capacity of the photovoltaic layer 302. Also, the through silicon vias 306 and 308 respectively have second opposing ends 306b and 308b electrically coupled to the second conductive layer 304. Each through silicon via can extend from the light receiving top node 302a of the photovoltaic layer 302 through the photovoltaic layer 302 and the first conductive layer 303 to the second conductive layer 304, so there are conductive paths 320 and 322 between the light receiving top node 302a and the second conductive layer 304. The conductive paths 320 and 322 are not limited to a vertical configuration, as depicted in FIG. 3, but may be configured horizontally or in any other slope. The through silicon vias 306 and 308 including the conductive paths 320 and 322 are electrically insulated (i.e., isolated) from the photovoltaic layer 302 and the first conductive layer 303. Further, multiple through silicon vias can be arranged across the photovoltaic layer 302, thus providing electrical contact points on the top surface of the photovoltaic layer 302.

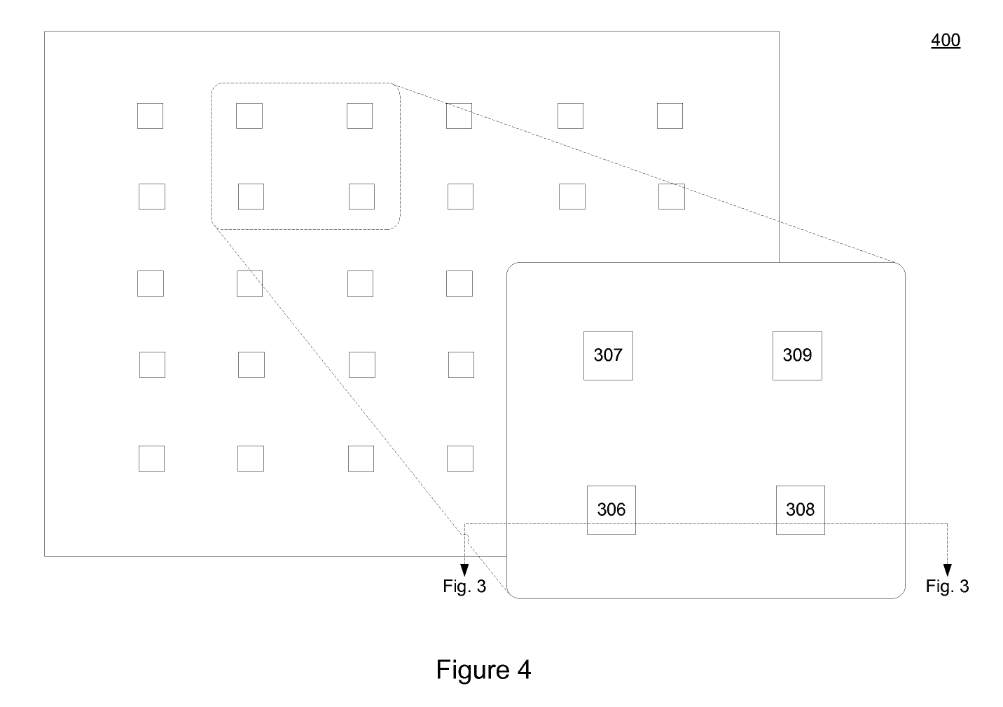

A light refracting layer 314 is positioned on the light receiving top node 302a to deflect light into the photovoltaic layer 302, and reduce the amount of light reflected (e.g., photon 316b). In another embodiment, the light refracting layer 314 is electrically coupled to the light receiving top node 302a. The light refracting layer 314 having translucent properties can deflect light photons (e.g., photon 316a) into the photovoltaic layer 302 and electrically conduct the generated electricity from the photovoltaic layer 302 to the through silicon via array 400 as to be described below in FIG. 4. Moreover, the light refracting layer 314 can be made of the Indium-Tin-Oxide material, or of other conductive materials. Further, having the through silicon vias spaced relatively close to each other reduces the internal resistance, thus allowing the thickness of the light refracting layer 314 to be reduced so more light can penetrate the photovoltaic layer 302.

The through silicon via connections to the light refracting layer 314 reduce or eliminate the need of having metallization requirements exist above the photovoltaic layer 302 because the through silicon vias can provide passage to the second conductive layer 304 through the body of the photovoltaic layer 302. For example, instead of having metal traces positioned on top of the photovoltaic cell 300 as shown in FIG. 2, any electrical connection between the light receiving top node 302a and the second conductive layer 304 would travel through the through silicon vias 306 and 308 while reducing the area of the light receiving top node 302a that obstructs the light from entering the photovoltaic layer 302 so as to improve efficiency. Although the terminology “through silicon via” includes the word silicon, it is noted that through silicon vias are not necessarily constructed in silicon. Rather, the material can be any device substrate material. In some embodiments, the photovoltaic cell 300 and the above-described elements may be varied and are not limited to the functions, structures, configurations, implementations, or examples provided.

FIG. 4 is a top view of the photovoltaic cell 300 (FIG. 3) that includes the photovoltaic layer 302 with through silicon vias 306, 307, 308, and 309 electrically coupled to the light receiving top node 302a (FIG. 3). The through silicon vias 306, 307, 308, and 309 are in an electrically conductive relationship with each other on the photovoltaic layer 302, which have an effect on the internal resistance between the through silicon vias. The through silicon vias can be positioned in spaced relationship to each other along the light receiving top node 302a of the photovoltaic layer 302, thus forming a through silicon via array 400. The through silicon via array 400 provides any desired number of electrical contact points between the photovoltaic layer 302 and the light refracting layer 314 to provide more conductive paths to the second conductive layer 304 so to improve efficiency. Moreover, the internal resistances of the photovoltaic cell 300 can be reduced by either spacing the through silicon vias closer to each other or increasing the surface area of the second conductive layer 304 (FIG. 3). The spacing between each through silicon via can be adjusted according to the amount of internal resistance allowable by design requirements. In some embodiments, the through silicon via array 400 and the above-described elements may be varied and are not limited to the functions, structures, configurations, implementations, or examples provided.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A photovoltaic cell, comprising:
a photovoltaic layer having a first node and a second node;
a first conductive layer electrically coupled to the first node of the photovoltaic layer so the first conductive layer does not block light from the photovoltaic layer;
a second conductive layer adjacent to but electrically insulated from the first conductive layer, the second conductive layer being positioned so the second conductive layer does not block light from the photovoltaic layer; and
at least one through silicon via electrically coupled to both the first node of the photovoltaic layer and the second conductive layer, the through silicon via being electrically insulated from at least a portion of the photovoltaic layer and the first conductive layer.

2. The photovoltaic cell of claim 1, further comprising a light refracting layer that deflects the light into the photovoltaic layer and is adjacent to the first node of the photovoltaic layer.

3. The photovoltaic cell of claim 2, wherein the light refracting layer is an electrode layer that is electrically coupled to the photovoltaic layer and at least one through silicon via.

4. The photovoltaic cell of claim 1, wherein the through silicon via extends from the first node of the photovoltaic layer through the photovoltaic layer and the first conductive layer to the second conductive layer and provides a conductive path from the first node to the second conductive layer.

5. A solar cell, comprising:
a photovoltaic layer having a light receiving top node and a bottom node;
an electrode layer that is adjacent to and electrically coupled to the light receiving top node of the photovoltaic layer, and deflects light into the photovoltaic layer;
a first conductive layer electrically coupled to the bottom node of the photovoltaic layer;
a second conductive layer adjacent to and electrically insulated from the first conductive layer, so the second conductive layer does not block the photovoltaic layer from any light; and
at least one through silicon via that is electrically coupled between the light receiving top node of the photovoltaic layer through the photovoltaic layer and the first conductive layer to the second conductive layer, but electrically insulated from the photovoltaic layer and the first conductive layer.

6. The solar cell of claim 5, wherein the through silicon via further comprises a first end that is exposed at the light receiving top node and electrically coupled to the electrode layer.

7. The solar cell of claim 5, wherein the through silicon via is spaced relative to another through silicon via in an electrically conductive relationship so to form a through silicon via array.

8. The solar cell of claim 5, wherein the electrode layer further comprises Indium-Tin-Oxide.

9. The solar cell of claim 5, wherein the electrode layer absorbs light reflected from the at least one through silicon via.

10. The solar cell of claim 5, further comprising a load that promotes current flow between the first conductive layer and the second conductive layer.

11. An apparatus for reducing obstruction of light to a photovoltaic cell, comprising:
means for receiving light and absorbing the light to generate electricity between polarized nodes;
first means for conducting electricity from a first polarized node of the light receiving means while not blocking light from the light receiving means; and
second means for conducting electricity from a second polarized node of the light receiving means while not blocking light from the light receiving means.

12. The apparatus of claim 11, wherein the first means for conducting electricity further comprises means for electrically coupling a conductive layer, through the light receiving means, to the first polarized node, the electrically coupling means being electrically insulated from the light receiving means.

13. The apparatus of claim 12, wherein the electrically coupling means further comprises a through silicon via.

14. The apparatus of claim 11, further comprising means for deflecting light into the light receiving means.

15. A method of reducing blocked light to a solar cell, comprising:
positioning a photovoltaic layer having a first node and a second node;
positioning a first conductive layer adjacent to and electrically coupled to the second node of the photovoltaic layer so the first conductive layer does not block light from the photovoltaic layer;
positioning a second conductive layer adjacent to and electrically insulated from the first conductive layer, so the second conductive layer does not block light from the photovoltaic layer; and
fabricating at least one through silicon via between the first node of the photovoltaic layer through the photovoltaic layer and the first conductive layer to the second conductive layer, the at least one through silicon via being electrically insulated from the photovoltaic layer and the first conductive layer.

16. The method of claim 15, further comprising positioning an electrode layer adjacent to and electrically coupled to the first node of the photovoltaic layer to deflect light into the photovoltaic layer.

17. The method of claim 16, further comprising fabricating the second conductive layer to at least the size of the first conductive layer to reduce thickness of the electrode layer.

18. The method of claim 15, wherein fabricating at least one through silicon via further comprises spacing at least one through silicon via relative to at least one other through silicon via in an electrically conductive relationship to form a through silicon via array.
